(19) United States
(12) Patent Application Publication
(10) Pub. No.: US 2014/0376323 A1
(43) Pub. Date: Dec. 25, 2014

(54) SEMICONDUCTOR DEVICE

(71) Applicant: PS4 LUXCO S.A.R.L., Luxembourg (LU)

(72) Inventor: Yoshifumi TERADA, Tokyo (JP)

(21) Appl. No.: 14/310,722

(22) Filed: Jun. 20, 2014

(30) Foreign Application Priority Data
Jun. 24, 2013 (JP) 2013-131578

(51) Int. Cl. G11C 11/408

(52) U.S. Cl. CPC G11C 11/4087
USPC 365/230.03

(57) ABSTRACT

A plurality of memory banks bank through bank is provided. Each memory bank includes a row decoder that selects a main word line based on a row address, a column decoder that selects a column selection line based on a column address, and a memory cell array made up of a plurality of memory cells. The memory cell array included in the memory bank bank is divided into a plurality of memory blocks MB that differ by a power of. According to the present invention, the memory cell array can be more flexibly laid out. Therefore, the chip shape can be a shape that is close to a square without providing a large empty space.

### TECHNICAL FIELD

The present invention relates to a semiconductor device, and more particularly to a semiconductor device in which each memory bank is divided into a plurality of memory blocks.

### BACKGROUND ART

It is common for semiconductor devices as typified by dynamic random access memory (DRAM) to have a memory cell array region divided into a plurality of memory banks.

A memory bank is an issuing unit of commands and non-exclusive access to different memory banks is possible. Therefore, access efficiency can be increased dividing the memory cell array region into a plurality of memory banks.

The shape of each memory bank is limited by its storage capacity, and in many cases, such shape is close to a square or a rectangle where the ratio of the long side to the short side is about 2:1. As one example, with a two gigabit DRAM having an eight bank configuration, because the storage capacity of one bank is 256 megabits, one bank can be configured by forming an array of 16 k memory cells in a word line direction and 16 k memory cells in a bit line direction. In this case, the shape of each memory bank is close to a square. Conversely, with a four gigabit DRAM having an eight bank configuration, because the storage capacity of one bank is 512 megabits, one bank can be formed by forming an array of 32 k memory cells in the word line direction and 16 k memory cells in the bit line direction. In this case, the shape of each memory bank is a rectangle where the ratio of the long side to the short side is about 2:1.

On the other hand, DRAMs referred to as edge-pads have been widely used in recent years. Edge-pad type DRAMs are DRAM types that have pad electrodes formed in an array along two opposing chip edges, and two chips can be stacked in a state of being rotated at 90° with respect to each other.

To stack edge-pad type DRAMs, the chip shape is a rectangle close to a square, and it is required for the pad electrodes to be arranged in an array along the short side. Here, a rectangle close to a square is required because when the difference of the length of the long side and the short side is too large, it is easy for deflection to occur on the chip positioned on the upper layer when stacked in a 90° rotated state. Meanwhile, it is necessary to arrange the pad electrodes along the short side because the pad electrode of the chip positioned on the lower layer is exposed when stacked in a 90° rotated state.

### BACKGROUND DOCUMENTS

### Patent Documents

Patent Document 2: Japanese Unexamined Patent Application Publication No. 2009-295740A

### SUMMARY OF INVENTION

### Technical Problem

However, it has sometimes been difficult for the chip shape to be a shape close to a square depending on the storage capacity of the chip or the bank configuration. For example, when the shape of each memory bank on a chip of an eight bank configuration is a rectangle with a ratio of 2:1, the chip shape is close to a square if the eight memory banks are laid out in 2 columns×4 rows. On the other hand, when the shape of each memory bank on a chip with an eight bank configuration is a shape close to a square, a large empty space occurs in order to make the chip shape a shape that is close to a square. With the example illustrated in Patent Document 1, the eight memory banks are laid out in 3 columns×3 rows, and the central region is an empty space.

Peripheral circuits for controlling the memory cell array can be disposed in the empty space, but because it is the same size as one memory bank, there is often wasted space.

### Solution to Problem

A semiconductor device according to a first aspect of the present invention is provided with a plurality of memory banks having a first memory bank that can be non-exclusively accessed, wherein the plurality of memory banks each includes a row decoder that selects one of a plurality of main word lines based on a row address, a column decoder that selects one of a plurality of column selection lines based on a column address, and a memory cell array made from a plurality of memory cells selected by the plurality of main word lines and the plurality of column selection lines; and the memory cell array included in the first memory bank is divided into a plurality of memory blocks that differ by a power of 2 and are defined by an extending range of one of the plurality of main word lines and one of the plurality of column selection lines that intersect each other.

A semiconductor device according to a second aspect of the present invention is provided with a plurality of memory banks having a first memory bank that can be non-exclusively accessed, wherein the plurality of memory banks each includes a row decoder that selects one of a plurality of main word lines based on a row address, a column decoder that selects one of a plurality of column selection lines based on a column address, and a memory cell array made up of a plurality of memory cells selected by the plurality of main word lines and the plurality of column selection lines; and the memory cell array included in the first memory bank is divided into a plurality of memory blocks that includes at least a first and a second memory block and that is defined by the extending range of one of the plurality of main word lines and one of the plurality of column selection lines that intersect each other, wherein the plurality of memory blocks includes a plurality of memory mats each selected by the plurality of main word lines, and the number of the plurality of memory mats included in the first memory block is different than the number of the plurality of memory mats included in the second memory block.

A semiconductor device according to a third aspect of the present invention is provided with a first memory bank including first through third memory blocks, a second memory bank including fourth through sixth memory blocks, a first lead amplifier assigned in common to the first memory block and the third memory block, a second lead amplifier assigned in common to the second memory block and the fifth memory block, and a third lead amplifier assigned in common to the fourth memory block and the sixth memory block.

### Advantageous Effects of Invention

According to a semiconductor device of the first aspect of the present invention, the memory cell array can be more flexibly laid out because the memory bank is divided into a plurality of memory blocks that differ by a power of two. Therefore, the chip shape can be a shape close to a square without providing a large empty space.

According to a semiconductor device of the second aspect of the present invention, the memory cell array can be more flexibly laid out because the memory bank is divided into a plurality of memory blocks with a different number of memory mats. Therefore, the chip shape can be a shape close to a square without providing a large empty space.

According to a semiconductor device of the third aspect of the present invention, the memory cell array can be more flexibly laid out because a lead amplifier shared between different memory banks and a lead amplifier not shared between different memory banks are both present. Therefore, the chip shape can be a shape close to a square without providing a large empty space.

### BRIEF DESCRIPTION OF THE DRAWINGS

FIG. 1 is a schematic plan view illustrating the exterior of a semiconductor device 10 according to a preferred embodiment of the present invention.

FIG. 2 is a schematic plan view illustrating two semiconductor devices 10A and 10B stacked in a 90° mutually rotated state.

FIG. 3 is a block diagram illustrating an internal circuit of a semiconductor device 10.

FIG. 4 is a schematic plan view for describing a rough layout of the semiconductor device 10.

FIG. 5 is a diagram illustrating an example of a memory bank being configured by one memory block.

FIG. 6 is a schematic plan for describing a configuration of a memory block.

FIG. 7 is a schematic plan view for describing a configuration of a memory mat MAT.

FIG. 8 is a schematic view for describing an address mapping of the memory mat MAT.

FIG. 9 is a schematic plan view illustrating one example of a layout where the semiconductor device 10 is a four gigabit DRAM having an eight bank configuration.

FIG. 10 is a schematic plan view illustrating a first example of a layout where the semiconductor device 10 is an eight gigabit DRAM having an eight bank configuration.

FIG. 11 is a schematic plan view illustrating a second example of a layout where the semiconductor device 10 is an eight gigabit DRAM having an eight bank configuration.

FIG. 12 is a schematic plan view illustrating a third example of a layout where the semiconductor device 10 is an eight gigabit DRAM having an eight bank configuration, and corresponds to the first embodiment of the present invention.

FIG. 13 is an enlarged view of memory banks bank0 and bank4.

FIG. 14 is a diagram illustrating segments SEG0 to SEG2.

FIG. 15 is a table for describing an address mapping of a segment, 15 (a) illustrates an address mapping corresponding to the segment SEG0, 15 (b) illustrates an address mapping corresponding to the segment SEG1, and 15 (c) illustrates an address mapping corresponding to the segment SEG2.

FIG. 16 is a circuit diagram of a decoder circuit that generates the segments SEG0 to SEG2.

FIG. 17 is a diagram illustrating the segments SEG0 to SEG2 included in the memory banks bank0 and bank4.

FIG. 18 is a circuit diagram illustrating a main part of an access control circuit 20.

FIG. 19 is a timing diagram for describing an operation of the circuit illustrated in FIG. 18.

FIG. 20 is a circuit diagram of a column decoder 13.

FIG. 21 is a circuit diagram of an amplifier circuit 15.

FIG. 22 is a timing diagram for describing an operation of the circuits illustrated in FIGS. 20 and 21.

FIG. 23 is a schematic view illustrating a configuration of a segment according to a modified example.

FIG. 24 is a schematic plan view illustrating a fourth example of a layout where the semiconductor device 10 is an eight gigabit DRAM having an eight bank configuration, and corresponds to the second embodiment of the present invention.

FIG. 25 is a schematic plan view illustrating a fifth example of a layout where the semiconductor device 10 is an eight gigabit DRAM having an eight bank configuration, and corresponds to the third embodiment of the present invention.

FIG. 26 is a schematic plan view illustrating a sixth example of a layout where the semiconductor device 10 is an eight gigabit DRAM having an eight bank configuration, and corresponds to the fourth embodiment of the present invention.

FIG. 27 is a schematic plan view illustrating a seventh example of a layout where the semiconductor device 10 is an eight gigabit DRAM having an eight bank configuration, and corresponds to the fifth embodiment of the present invention.

### DETAILED DESCRIPTION OF THE INVENTION

In the following, preferred embodiments of the present invention are described in detail with reference to the appended drawings.

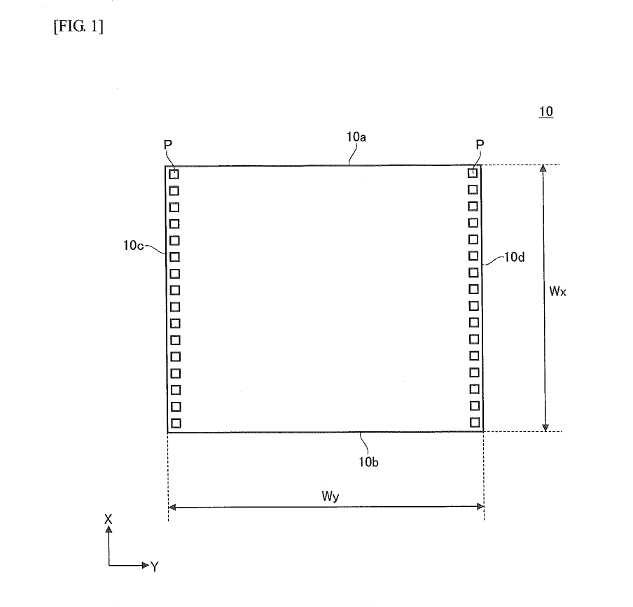

FIG. 1 is a schematic plan view illustrating the exterior of a semiconductor device according to a preferred embodiment of the present invention. The semiconductor device 10 according to the present embodiment is a DRAM, but the application of the present invention is not limited thereto.

As illustrated in FIG. 1, the planar shape of the semiconductor device 10 according to the present embodiment is a rectangular shape close to a square, and has edges 10a and 10b on the long side along the Y-direction, and edges 10c and 10d on the short side along the X-direction. When the length of the edges 10a and 10b on the long side is Wy and the length of the edges 10c and 10d on the short side is Wx, then

Wx<Wy.

The semiconductor device 10 according to the present embodiment is provided with a plurality of pad electrodes P arranged along the edges 10c and 10d on the short side.

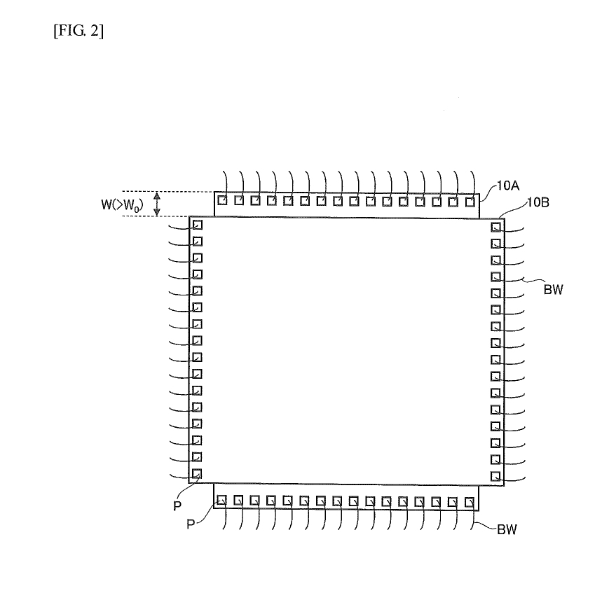

The semiconductor device 10 that has this type of configuration may be packaged individually, but it is also possible to stack and package two of the semiconductor devices 10. In this case, two semiconductor devices 10A and 10B are rotated 90° with respect to each other and stacked as illustrated in FIG. 2. In this manner, a bonding wire BW can be connected to the pad electrode P because the pad electrode P provided on the semiconductor device 10A on the lower layer is exposed. When an exposure width on the semiconductor device 10A on the lower layer is defined as W, then

Wx+2W=Wy,

and it is necessary for the exposure width W to be a minimum width W0 capable of being bonded by a wire to the pad electrode P or greater.

However, when Wy is too large with respect to Wx, it is easy for warping to occur on the semiconductor device 10B of the upper layer because the short side (edges 10c and 10d) of the semiconductor device 10B on the upper layer is largely protruding from the long side (edges 10a and 10b) of the semiconductor device 10A of the lower layer. Because this warping causes reduced reliability, it must be suppressed as much as possible. To suppress warping, it is desirable to make the difference (=2W) between Wx and Wy as small as possible, that is to say, make it a shape close to a square, within a range that satisfies W>W0.

To make the planar shape of the semiconductor device 10 a shape that is close to a square, it is necessary to optimize the layout of the inner circuit, and particularly the memory cell array.

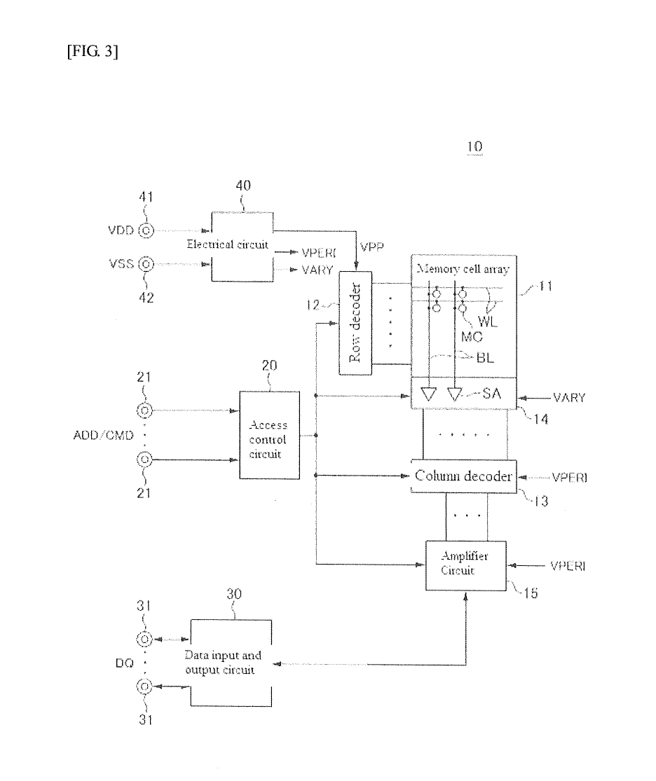

FIG. 3 is a block diagram illustrating an internal circuit of the semiconductor device 10.

As illustrated in FIG. 3, the semiconductor device 10 according to the present embodiment is provided with a memory cell array 11. A plurality of word lines WL and a plurality of bit lines BL are provided intersecting each other on the memory cell array 11, and a memory cell MC is positioned on that intersection. Selection of the word lines WL is performed by a row decoder 12, and selection of the bit lines BL is performed by a column decoder 13. The bit lines BL are each connected to a corresponding sense amplifier SA in a sense circuit 14, and the bit lines BL selected by the column decoder 13 are connected to an amplifier circuit 15 via the sense amplifier SA.

The operations of the row decoder 12, the column decoder 13, the sense circuit 14, and the amplifier circuit 15 are controlled by an access control circuit 20. An address signal ADD and a command signal CMD are supplied from the exterior to the access control circuit 20 via a plurality of command address terminals 21. The access control circuit 20 receives the address signal ADD and the command signal CMD, and controls the row decoder 12, the column decoder 13, the sense circuit 14, and the amplifier circuit 15 based on these signals.

Specifically, the address signal ADD is supplied to the row decoder 12 when the command signal CMD shows active operation of the semiconductor device 10. In response to this, the row decoder 12 selects the word lines WL shown by the address signal ADD, and the corresponding memory cells MC are thereby each connected to the bit lines BL. Next, the access control circuit 20 activates the sense circuit 14 with a predetermined timing.

Meanwhile, the address signal ADD is supplied to the column decoder 13 when the command signal CMD shows a read operation or a write operation of the semiconductor device 10. In response, the column decoder 13 connects the bit lines BL shown by the address signal ADD to the amplifier circuit 15. In this manner, during the read operation, read data DQ read from the memory cell array 11 via the sense amplifier SA is output to the exterior from a data terminal 31 via the amplifier circuit 15 and a data input and output circuit 30. Furthermore, during the write operation, write data DQ supplied from the exterior via the data terminal 31 and the data input and output circuit 30 is written to the memory cell MC via the amplifier circuit 15 and the sense amplifier SA.

Each of these circuit blocks use a predetermined internal voltage as an operation power source. These internal power sources are generated by a power circuit 40 illustrated in FIG. 3. The power circuit 40 receives an external potential VDD and a ground potential VSS each supplied via power terminals 41 and 42, and generates internal voltages VPP, VPERI, VARY and the like based on these potentials. The internal potential VPP is generated by boosting the external potential VDD, and the internal potentials VPERI and VARY are generated by stepping down the external potential VDD.

The internal voltage VPP is the voltage used mainly on the row decoder 12. The row decoder 12 drives the word lines WL selected based on the address signal ADD to the VPP level, and conduction of a cell transistor included in the memory cell MC is thereby caused. The internal voltage VARY is the voltage used mainly in the sense circuit 14. When the sense circuit 14 is activated, an amplification of read data that has been read is performed by driving one of the bit lines to the VARY level and the other bit line to the VSS level. The internal voltage VPERI is used as an operating voltage for a large portion of the peripheral circuits such as the access control circuit 20 or the like. By using the internal voltage VPERI that is lower than the external voltage VDD as the operating voltage for these peripheral circuits, low power consumption is achieved in the semiconductor device 10.

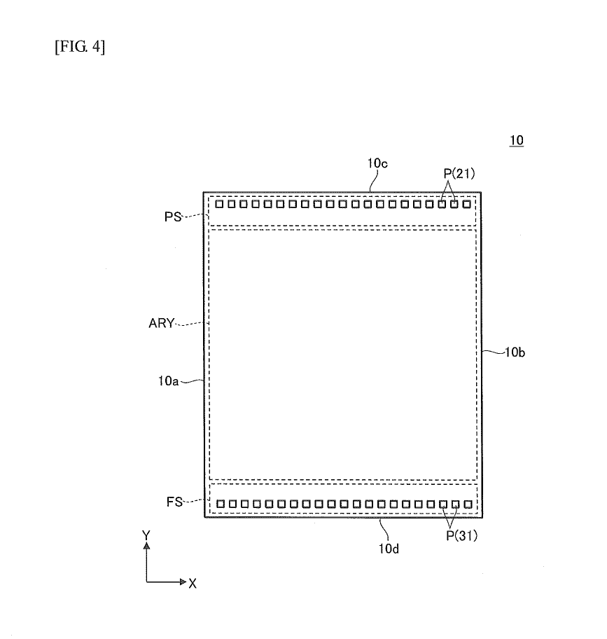

FIG. 4 is a schematic plan view for describing a rough layout of the semiconductor 10.

As illustrated in FIG. 4, the semiconductor device 10 is provided with a peripheral circuit region PS provided along the edge 10c of the short side and a peripheral circuit region FS provided along the edge 10d of the short side, and a memory cell array region ARY is disposed sandwiched therebetween. The pad electrode P configuring one portion of the command address terminal 21 and the power terminals 41 and 42 is arranged on the peripheral circuit region PS, where the access control circuit 20 is also disposed. Meanwhile, the pad electrode P configuring the other portion of the data terminal 31 and the power terminals 41 and 42 is arranged on the peripheral circuit region FS, where the data input and output circuit 30 is also disposed. Next, the memory cell array 11, the row decoder 12, the column decoder 13, the sense circuit 14, and the amplifier circuit 15 are disposed on the memory cell array region ARY sandwiched by the above.

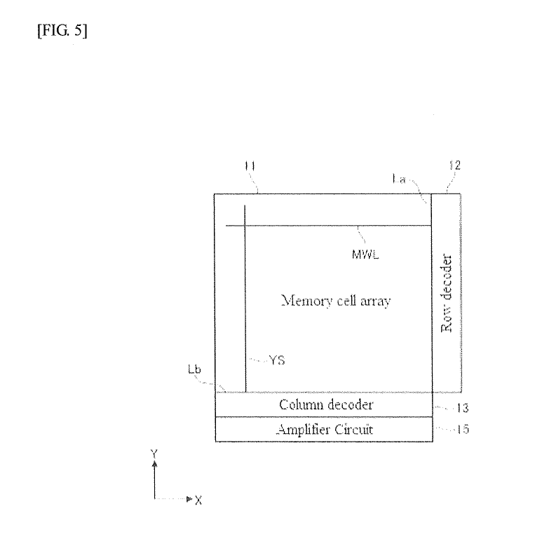

The memory cell array 11 is divided into a plurality of memory banks, and row decoders 12 and column decoders 13 and the like are also provided on each memory bank. FIG. 5 is a plan view illustrating one example of one memory bank layout, and the rectangular memory cell array 11, the row decoder 12 disposed along a side La of the memory cell array 11, the column decoder 13 disposed along a side Lb of the memory cell array 11, and the amplifier circuit 15 are provided in the example illustrated in FIG. 5. The sense circuit 14 is embedded in an inner portion of the memory cell array 11.

However, it may be difficult to adopt the layout illustrated in FIG. 5 depending on the storage capacity of the memory bank, and there are times when one memory bank is divided into multiple memory blocks. This is because when the storage capacity of a memory bank becomes large, the load capacity of a main word line MWL extending from the row decoder 12 to the memory cell array 11 becomes large, or the load capacity of a column selection line YS extending from the column decoder 13 to the memory cell array 11 becomes large. Here, a memory block is a region defined by the extending range of the main word line MWL and the column selection line YS that intersect each other.

With the current art, 256 megabits (=16 k words×16 k bits) is the realistic maximum size of the memory block, and it becomes necessary to divide one memory bank into a plurality of memory blocks when the capacity of one memory bank exceeds this.

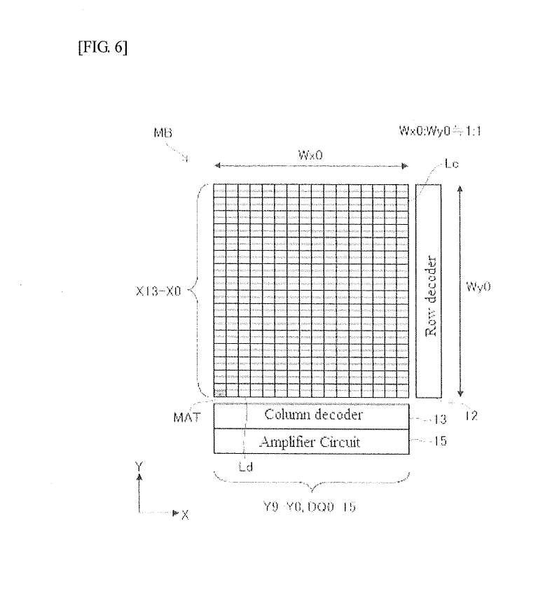

FIG. 6 is a schematic plan for describing a configuration of a memory block.

As illustrated in FIG. 6, a memory block MB is provided with a memory mat MAT laid out in a matrix 16 columns by 33 rows, the row decoder 12 is disposed along a side Lc of the memory block MB, and the column decoder 13 and the amplifier circuit 15 are disposed along a side Ld of the memory block MB.

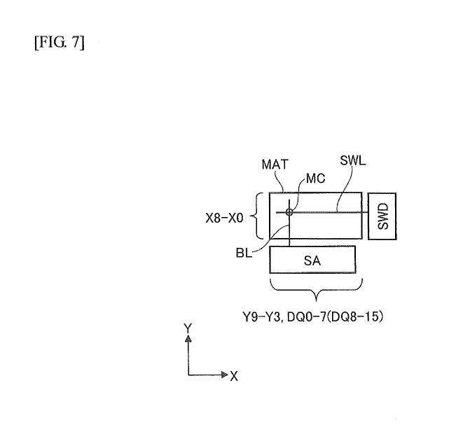

FIG. 7 is a schematic plan view for describing a configuration of a memory mat MAT.

As illustrated in FIG. 7, the memory mat MAT has a configuration that is provided with a plurality of sub-word lines SWL and the plurality of bit lines BL, and the memory cell MC is provided on the intersection of the lines thereof. The sub-word line SWL is driven by a sub-word driver SWD. Selection of the sub-word driver SWD is performed via the main word line MWL illustrated in FIG. 5 based on control by the row decoder 12. Furthermore, the bit lines BL are each connected to a corresponding sense amplifier SA, and when they are selected by the column selection line YS shown in FIG. 5, they are connected to the amplifier circuit 15 via a local input/output line and a main input/output line not illustrated.

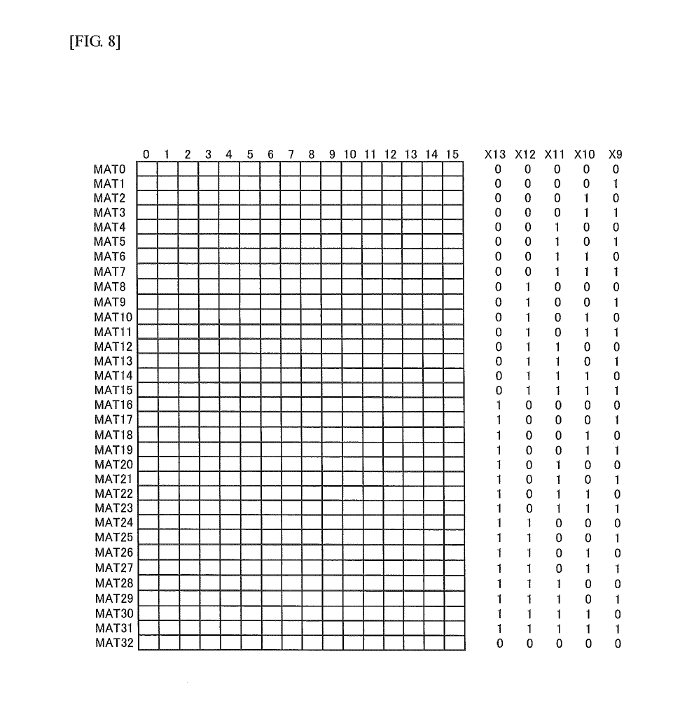

FIG. 8 is a schematic view for describing an address mapping of the memory mat MAT.

As illustrated in FIG. 8, selection of the memory mat MAT in the column direction (Y-direction) is performed by the main word line MWL based on upper bits X13 to X9 of a row address. Here, a memory mat MAT0 and a memory mat MAT32 positioned on an end portion of the column direction have a storage capacity of half of the other memory mats MAT1 to MAT31, and these two memory mats MAT0 and MAT 32 are treated as one memory mat MAT. Therefore, the same row address (X13 to X9=00000b) is mapped to the memory mat MAT0 and the memory mat MAT32. In the description below, the two memory mats MAT positioned on the end portion of the column direction are sometimes considered as one memory mat MAT for convenience.

Selection of the sub-word line SWL in the memory mat is performed using lower bits X8 to X0 of the row address as illustrated in FIG. 7. Therefore, 512 (=29) sub-word lines SWL are included in one memory mat MAT. In reality, there are times when more than 512 sub-word lines SWL are included in one memory mat MAT because there is a redundant word line for replacing defective sub-word lines SWL, but here, only regular sub-word lines SWL will be focused on.

Meanwhile, selection of the bit lines BL in the memory mat is performed using upper bits Y9 to Y3 of the column address as illustrated in FIG. 7. Furthermore, an 8 DQ amount (DQ0 to DQ7 or DQ8 to DQ15) of the bit lines BL selected at the same times are included in one memory mat MAT. Therefore, 1024 (=27×8) bit lines BL are included in one memory mat MAT. In reality, there are times when more than 1024 bit lines BL are included in one memory mat MAT because there is a redundant bit line for replacing defective bit lines BL, but here, only regular bit lines BL will be focused on.

Note that lower bits Y2 to Y0 of the column address are used for mapping in the row direction (X-direction) on the memory mat MAT. The eight memory mats MAT that have different mappings of the lower bits Y2 to Y0 are always selected at the same time, the data read from these eight memory mats MAT is prefetched by the data input and output circuit 30 illustrated in FIG. 2 and is burst output from the data terminal 31.

Then, this kind of memory mat MAT is laid out in a matrix of 16 columns×33 rows, and one memory block MB is configured. Therefore, one memory block MB has a configuration that is made up of 16 k (to be exact, 512×33 mats) bit lines BL in the row direction, and 16 k bit lines BL in the column direction, and memory cells MC are disposed at each of the intersections of these lines. Because of this, the size Wx0 in the X-direction and the size Wy0 in the Y-direction nearly become equal as illustrated in FIG. 6.

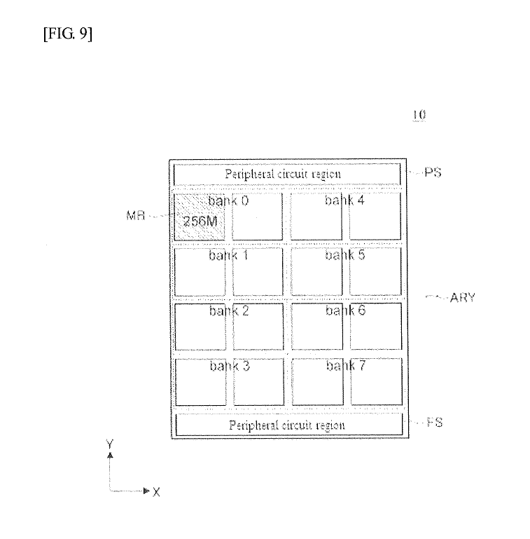

FIG. 9 is a schematic plan view illustrating one example of a layout where the semiconductor device 10 is a four gigabit DRAM having an eight bank configuration.

With a four gigabit DRAM having an eight bank configuration, it is necessary to configure one memory bank using two memory blocks MB illustrated in FIG. 6 because the storage capacity of one bank is 512 gigabits. In this case, the necessary number of memory blocks totals 16, and the memory blocks MB can therefore be laid out in a matrix of 4 columns by 4 rows as illustrated in FIG. 9. In this case, the shape of the memory cell array region ARY is nearly a square, and if the peripheral circuit regions PS and FS are disposed sandwiching it, the shape of the chip can be made a rectangle that is close to a square.

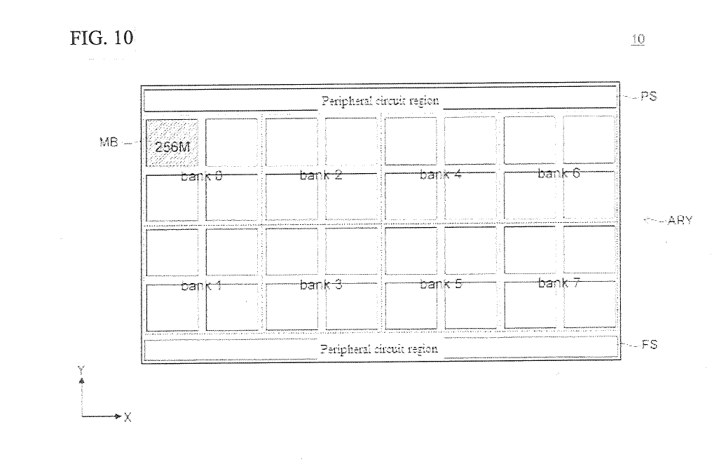

FIG. 10 is a schematic plan view illustrating a first example of a layout where the semiconductor device 10 is an eight gigabit DRAM having an eight bank configuration.

With an eight gigabit DRAM having an eight bank configuration, it is necessary to configure one memory bank using four memory blocks MB illustrated in FIG. 6 because the storage capacity of one bank is 1 megabit. In this case, the necessary number of memory blocks totals 32, and the memory blocks MB can therefore be laid out in a matrix of 8 columns by 4 rows as illustrated in FIG. 10. However, in this case, the shape of the chip cannot be a rectangle that is close to a square because the shape of the memory cell array region ARY is a 2:1 rectangle. Therefore, with this layout, it becomes impossible to stack the two semiconductor devices 10A and 10B as described using FIG. 2.

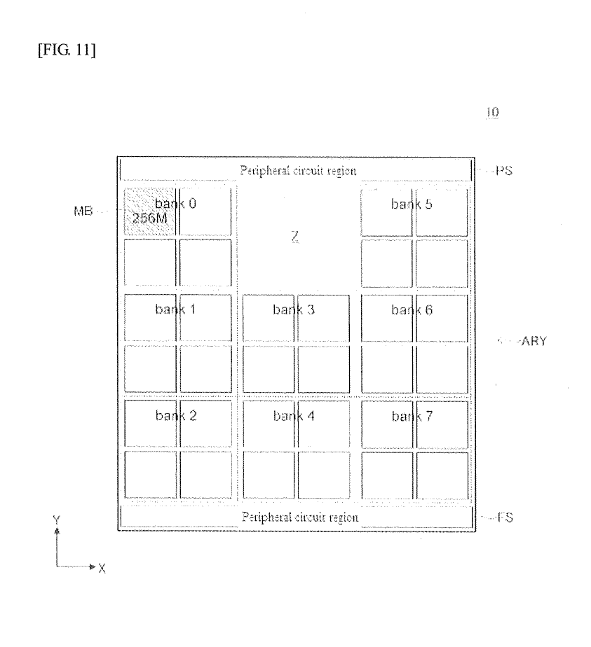

FIG. 11 is a schematic plan view illustrating a second example of a layout where the semiconductor device 10 is an eight gigabit DRAM having an eight bank configuration.

In FIG. 11, one memory bank is configured by laying out the memory blocks MB in a matrix of 2 columns×2 rows, and the memory banks are laid out in a matrix of 3 columns by 3 rows. In this case, the shape of the memory cell array region ARY is nearly a square, and if the peripheral circuit regions PS and FS are disposed sandwiching it, the shape of the chip can be made a rectangle that is close to a square. However, in this case, an empty space Z of one memory bank occurs in the memory cell array region ARY, and the chip surface area increases.

On the other hand, a layout described below generates almost no empty space Z, and it is possible for the shape of the chip to be a rectangle that is close to a square.

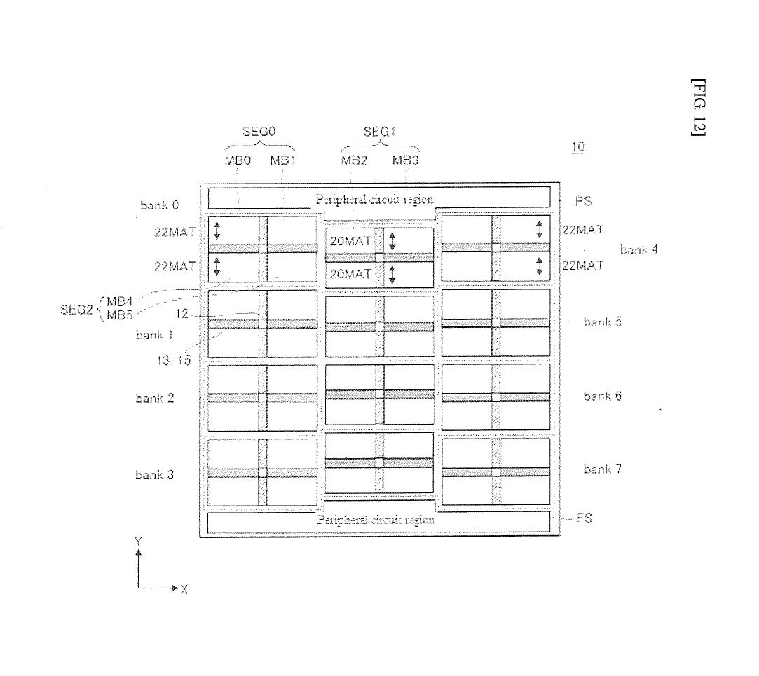

FIG. 12 is a schematic plan view illustrating the layout in a third example for a semiconductor device 10 having an eight gigabit DRAM with an eight bank configuration, and corresponds to the first embodiment of the present invention.

As illustrated in FIG. 12, one memory bank is divided into six memory blocks MB in the first embodiment. These six memory blocks MB are laid out in an L-shape, and a total of 12 memory blocks MB, which configure 2 memory banks, are combined such that an empty space is not produced.

Here, when describing in further detail with focus on the memory bank bank0, of the six memory blocks, MB0 to MB5, that configure the memory bank bank0, the two memory blocks MB0 and MB1 that are adjacent in the X direction configure the segment SEG0, the two memory blocks MB2 and MB3 that are adjacent in the X direction configure the segment SEG1, and the two memory blocks MB4 and MB5 that are adjacent in the X direction configure the segment SEG2. Segment SEG0 and segment SEG1 are disposed adjacent in the X direction, and segment SEG0 and segment SEG2 are disposed adjacent in the Y direction. Furthermore, a row decoder 12 is disposed between the two memory blocks that configure each segment.

With the present embodiment, the memory blocks MB that configure segments SEG0 and SEG2 each have 22 memory mats MAT in the Y direction, and the memory blocks MB that configure the segment SEG1 each have 20 memory mats MAT in the Y direction. By this, a total of 64 memory mats MAT are present in the Y direction. However, because the memory capacity of the memory mat MAT positioned at the end in the Y direction is half, as was already described, each memory block MB actually has one more memory mat MAT than the above mentioned number of memory mats MAT.

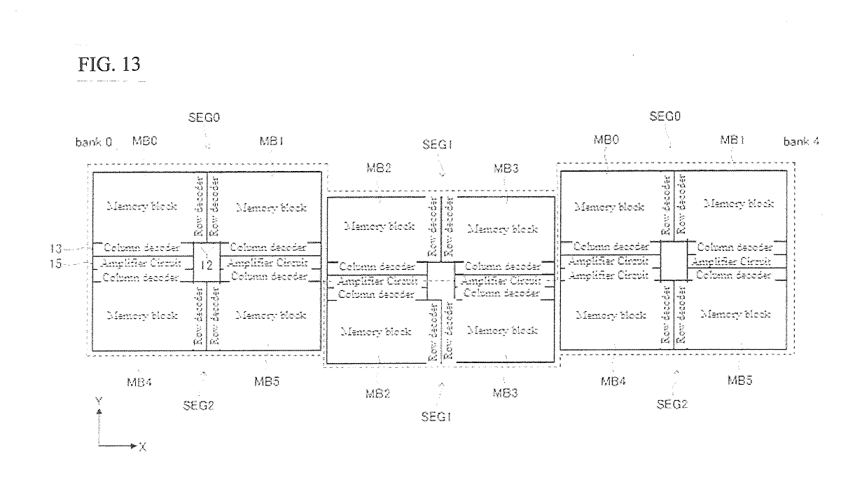

Here, when describing in further detail using FIG. 13, which is an enlarged view of the memory banks bank0 and bank4, the row decoder 12 assigned to each memory block MB is disposed between the two memory blocks that configure each segment. Furthermore, a column decoder 13 assigned to each memory block MB is disposed between the segment SEG0 and the segment SEG2, and an amplifier circuit 15 is disposed between the column decoders 13. Here, a portion of the circuit (a data amp described below) included in the amplifier circuit 15 is shared with the top and bottom segments. A portion of the circuit (the data amp described below) is also shared with the top and bottom segments of the amplifier circuit 15 disposed between the segment SEG1 of the memory bank bank0 and the segment SEG1 of the memory bank bank4. In other words, with the semiconductor device 10 according to the first embodiment, a portion of the data amp is shared with a different segment in the same bank, and the other data amps are shared with segments belonging to different banks.

With such a configuration, as illustrated in FIG. 12, each memory block MB can be laid out without producing a large empty space in the memory cell array region ARY. However, because the memory blocks MB2 and MB3 that configure the segment SEG1 are configured from a fewer number of memory mats MAT than the memory blocks MB0, MB1, MB4, and MB5 that configure segments SEG0 and SEG2, the height of segment SEG1 in the Y direction is lower than the heights of segments SEG0 and SEG2 in the Y direction. In the present embodiment, this type of segment SEG1 is disposed in the middle of the X direction, and the middle region in the X direction of the peripheral circuit regions PS and FS is projected in the Y direction by the amount for which the height of the segment SEG1 in the y direction is low.

With this type of layout, the semiconductor device 10 according to the first embodiment can obtain a rectangular chip shape that is close to a square. Furthermore, for each memory bank, a difference in the access conditions with respect to each memory bank does not occur because the configuration of the memory blocks MB are mutually equivalent.

However, because one memory bank is divided into a number (six in the present embodiment) of memory blocks MB that differs by a power of two, the number of memory mats MAT included in each memory block MB is a number that is not a power of two. Specifically, the memory blocks MB0, MB1, MB4, and MB5 are configured of 22 memory mats MAT in the Y direction, and the memory blocks MB2 and MB3 are configured of 20 memory mats MAT in the Y direction (the two memory mats MAT on the ends combine to be counted as one). All of the memory blocks MB in the X direction are made up of 16 memory mats MAT.

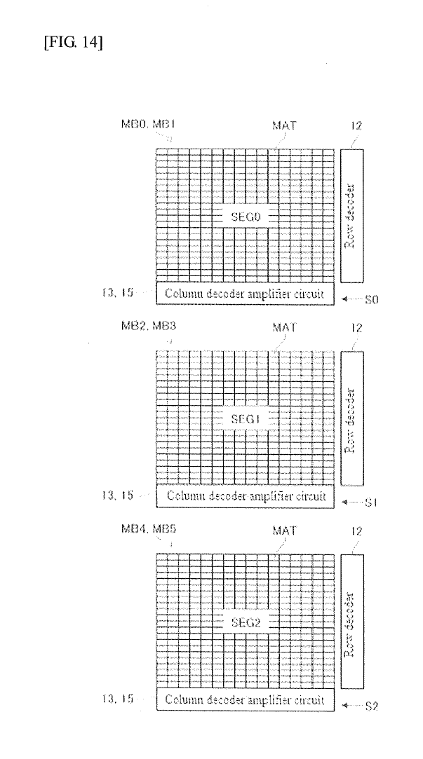

Therefore, with the present embodiment, a high-order bit of a low address is used to generate segment selection signals S0 to S2 as illustrated in FIG. 14, and using this, the column decoder 13 and the amplifier circuit 15 are selected.

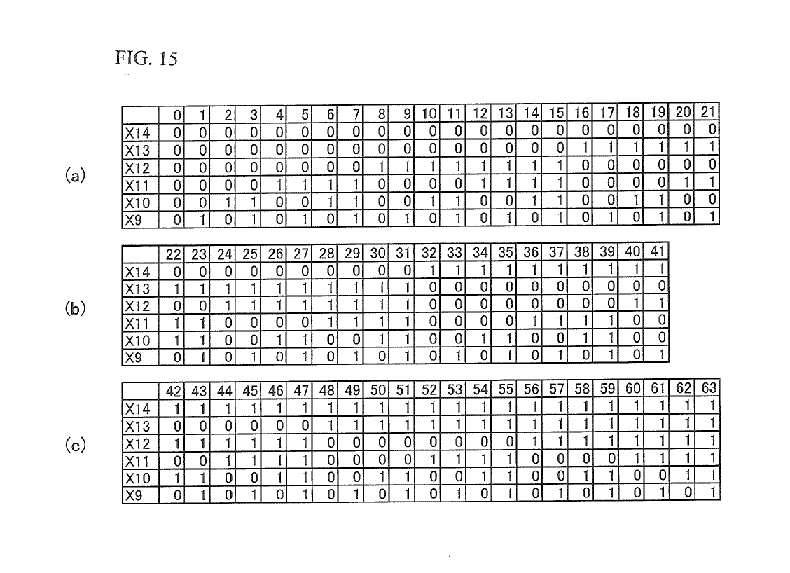

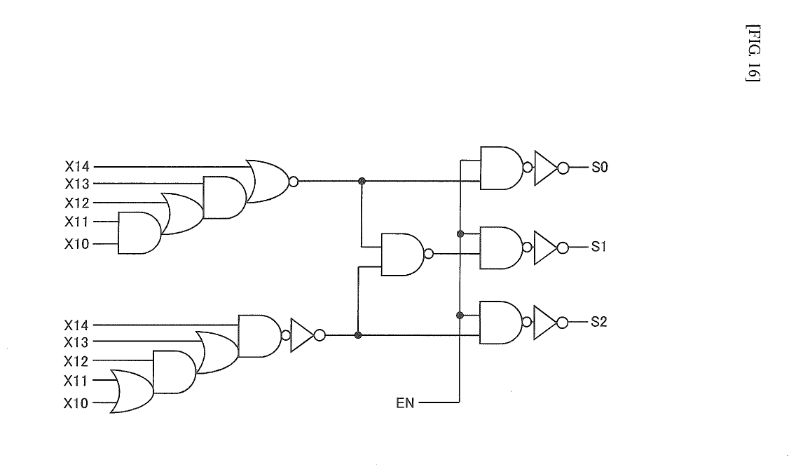

FIG. 15 is a table for describing an address mapping of a segment, 15 (a) illustrates an address mapping corresponding to the segment SEG0, 15 (b) illustrates an address mapping corresponding to the segment SEG1, and 15 (c) illustrates an address mapping corresponding to the segment SEG2. As shown in FIG. 15, the high-order bits X14 to X9 of the low address are used for the selection of segments SEG0 to SEG2. Specifically, segment selection signals S0 to S2 can be generated by using the decoder circuit illustrated in FIG. 16. Note that an enable signal EN illustrated in FIG. 16 is a signal for activating the column decoder 13 and the amplifier circuit 15 during column access.

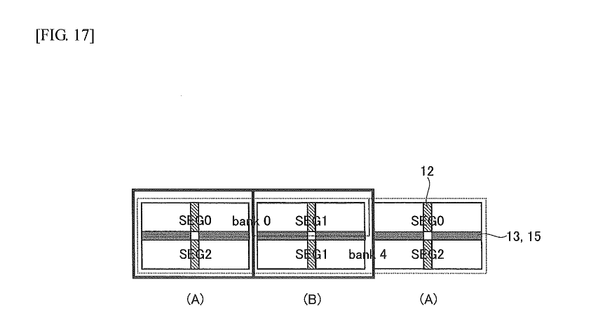

As illustrated in FIG. 17, with the present embodiment, the type (A) amplifier circuit 15 sandwiched between segments SEG0 and SEG2 of the same bank, and the type (B) amplifier circuit 15 sandwiched between segments SEG1 of a different bank are present. In contrast to the type (A) amplifier circuit 15, which is activated when SEG0 or SEG2 of the appropriate memory bank is selected, the type (B) amplifier circuit 15 must be activated when the segment SEG1 of the two memory banks positioned on top and below are selected.

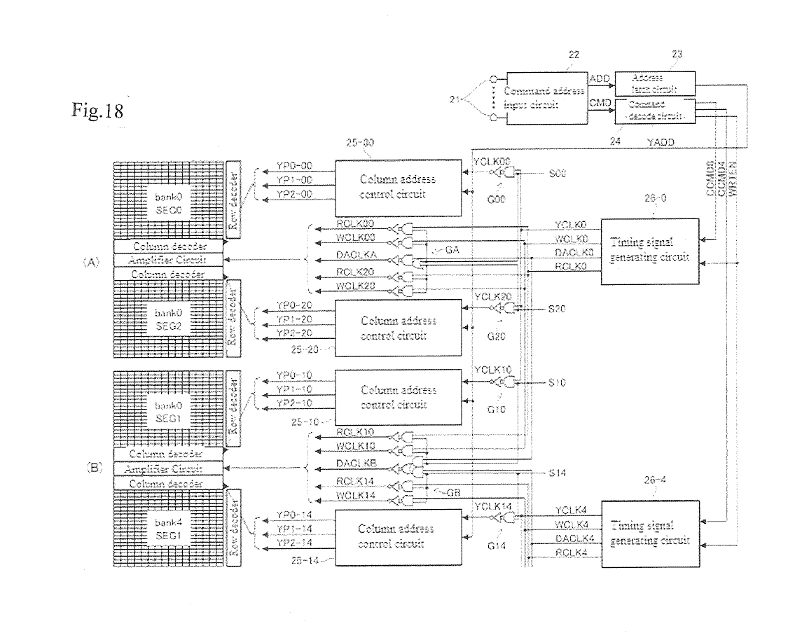

FIG. 18 is a circuit diagram illustrating a main part of an access control circuit 20.

As illustrated in FIG. 18, the access control circuit 20 is provided with a command address input circuit 22, an address latch circuit 23, and a command decoder circuit 24. The command address input circuit 22 is a circuit that inputs the address signal ADD and the command signal CMD via the command address terminal 21, and of these, the address signal ADD is supplied to the address latch circuit 23, and the command signal CMD is supplied to the command decoder circuit 24.

Of the address signals ADD latched to the address latch circuit 23, a column address YADD signal is supplied to a column address control circuit 25. The column address control circuit 25 is a pre-decoder circuit provided in each segment, and in FIG. 18, column address control circuits 25-00, 25-10, and 25-20 assigned respectively to segments SEG0, SEG1, and SEG2 of the memory bank0, and column address control circuit 25-14 assigned to segment SEG1 of the memory bank4 are illustrated. These column address control circuits 25-00, 25-10, 25-20, and 25-14 are activated by column clock signals YCLK00, YCLK10, YCLK20, and YCLK14 corresponding to each, and the pre-decoder signals YP0 to YP2 are generated by pre-decoding the column address YADD.

The command decoder circuit 24 is a circuit that generates various types of internal commands by decoding the command signal CMD. Of the internal commands generated by the command decoder circuit 24, FIG. 18 illustrates column signals CCMD0 and CCMD4 and a write enable signal WRTEN. Column signal CCMD0 is a signal that activates when the memory bank bank0 is designated and a read command or a write command is issued. In the same manner, column signal CCMD4 is a signal that activates when the memory bank bank4 is designated and a read command or a write command is issued. Meanwhile, the write enable signal WRTEN is a signal that activates when a write command is issued.

As illustrated in FIG. 18, the column signal CCMD0 and the write enable signal WRTEN are supplied to a timing signal generator circuit 26-0. The timing signal generator circuit 26-0 is a circuit assigned to the memory bank bank0, and generates a column clock signal YCLK0, a write clock signal WCLK0, a read clock signal RCLK0, and a data amp clock signal DACLK0 for the memory bank bank0. In the same manner, the timing signal generator circuit 26-4 is a circuit assigned to the memory bank bank4, and generates a column clock signal YCLK4, a write clock signal WCLK4, a read clock signal RCLK4, and a data amp clock signal DACLK4 for the memory bank bank4, based on the column signal CCMD4 and the write enable signal WRTEN.

Of these, the column clock signal YCLK0 is supplied to the AND gate circuits G00, G10, and G20 that receive a respective segment selection signal S00, S10, and S20, and by this, the column clock signals YCLK00, YCLK10, and YCLK20 are generated. The segment selection signals S00, S10, and S20 are signals that are activated when the segments SEG0 to SEG2 of each memory bank bank0 are selected, and are generated according to the circuit illustrated in FIG. 16. In the same manner, the column clock signal YCLK4 is supplied to an AND gate circuit G14 that receives a segment selection signal S14, and by this, a column clock signal YCLK14 is generated. Through this configuration, when a certain segment of a certain memory bank is selected, the column address control circuit 25 corresponding thereto is activated. Furthermore, the pre-decoder signals YP0 to YP2 are output from the activated column address control circuit 25, and are supplied to the corresponding column decoder 13. The configuration of the circuit of the column decoder 13 is described below.

Meanwhile, the write clock signals WCLK0 and WCLK4, the read clock signals RCLK0 and RCLK4, the data amp clock signals DACLK0 and DACLK4 are supplied to a logic gate circuit group GA, GB. The logic gate circuit group GA is a circuit that supplies each control signal to the type (A) amplifier circuit 15, and the logic gate circuit group GB is a circuit that supplies each control signal to the type (B) amplifier circuit 15.

The logic gate circuit group GA is activated by the segment selection signal S00 or S20, and generates write clock signals WCLK00 and WCLK20, read clock signals RCLK00 and RCLK20, and a data amp clock signal DACLKA. Of these, the write clock signal WCLK00 and the read clock signal RCLK00 are activated based on the write clock signal WCLK0 and the read clock signal RCLK0, under the condition that the segment selection signal S00 is activated. In the same manner, the write clock signal WCLK20 and the read clock signal RCLK20 are activated based on the write clock signal WCLK0 and the read clock signal RCLK0, under the condition that the segment selection signal S20 is activated. Furthermore, the data amp clock signal DACLKA is activated based on the data amp clock signal DACLK0, under the condition that the segment selection signal S00 or S20 is activated.

The logic gate circuit group GB is activated by the segment selection signal S10 or S14, and generates write clock signals WCLK10 and WCLK14, read clock signals RCLK10 and RCLK14, and a data amp clock signal DACLKB. Of these, the write clock signal WCLK10 and the read clock signal RCLK10 are activated based on the write clock signal WCLK0 and the read clock signal RCLK0, under the condition that the segment selection signal S10 is activated. In the same manner, the write clock signal WCLK14 and the read clock signal RCLK14 are activated based on the write clock signal WCLK4 and the read clock signal RCLK4, under the condition that the segment selection signal S14 is activated. Furthermore, the data amp clock signal DACLKB is activated based on the data amp clock signal DACLK0 when the segment selection signal S10 is activated, and is activated based on the data amp clock signal DACLK4 when the segment selection signal S14 is activated.

In this manner, the data amp block signal DACLKA, which controls the type (A) amplifier circuit 15, is activated when the segment SEG0 or SEG2 of the memory bank bank0 is selected. In contrast, the data amp block signal DACLKB, which controls the type (B) amplifier circuit 15, is activated when the segment SEG1 of the memory bank bank0 is selected, or when the segment SEG1 of the memory bank bank4 is selected.

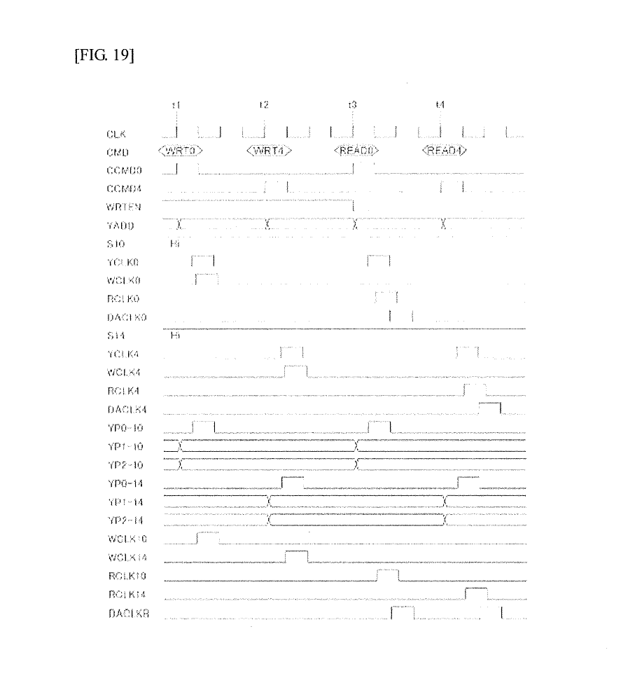

FIG. 19 is a timing diagram for describing an operation of the circuit illustrated in FIG. 18.

In an example illustrated in FIG. 19, a write command (WRT0) that designates the memory bank bank0 is issued at a time t1, a write command (WRT4) that designates the memory bank bank4 is issued at a time t2, a read command (READ0) that designates the memory bank bank0 is issued at a time t3, and a read command (READ4) that designates the memory bank bank4 is issued at a time t4. Although not illustrated in FIG. 19, both memory banks bank0 and, bank4, and the sub-word line SWL belonging to segment SEG1 are active due to an active command issued before time t1. Therefore, the segment selection signals S10 and S14 are in an active state.

First, the column signal CCMD0 is activated when the write command WRT0 is issued at the time t1, and in response to this, the column clock signal YCLK0 and the write clock signal WCLK0 are activated in order. At this time, because the segment selection signal S10 is in an activated state, pre-decoder signals YP0-10, YP1-10, and YP2-10 are generated by the column address control circuit 25-10, and the write clock signal WCLK10 is generated by the logic gate circuit group GB. Through this, the write data is write to the segment SEG1 of the memory bank bank0 through the type (B) amplifier circuit 15.

Next, the column signal CCMD4 is activated when the write command WRT4 is issued at the time t2; in response to this, the column clock signal YCLK4 and the write clock signal WCLK4 are activated in order. At this time, because the segment selection signal S14 is in an activated state, pre-decoder signals YP0-14, YP1-14, and YP2-14 are generated by the column address control circuit 25-14, and the write clock signal WCLK14 is generated by the logic gate circuit group GB. Through this, the write data is written to the segment SEG1 of the memory bank bank4 through the type (B) amplifier circuit 15.

In addition, the column signal CCMD0 is activated when the read command READ0 is issued at the time t3, and in response to this, the column clock signal YCLK0, the read clock signal RCLK0, and the data amp clock signal DACLK0 are activated in order. At this time, because the segment selection signal S10 is in an activated state, pre-decoder signals YP0-10, YP1-10, and YP2-10 are generated by the column address control circuit 25-10, and the read clock signal RCLK10 and the data amp clock signal DACLKB are generated by the logic gate circuit group GB. Through this, the read data is read from the segment SEG1 of the memory bank bank0 through the type (B) amplifier circuit 15.

Furthermore, the column signal CCMD4 is activated when the read command READ4 is issued at the time t4, and in response to this, the column clock signal YCLK4, the read clock signal RCLK4, and the data amp clock signal DACLK4 are activated in order. At this time, because the segment selection signal S14 is in an activated state, pre-decoder signals YP0-14, YP1-14, and YP2-14 are generated by the column address control circuit 25-14, and the read clock signal RCLK14, and the data amp clock signal DACLKB are generated by the logic gate circuit group GB. Through this, the read data is read from the segment SEG1 of the memory bank bank4 through the type (B) amplifier circuit 15.

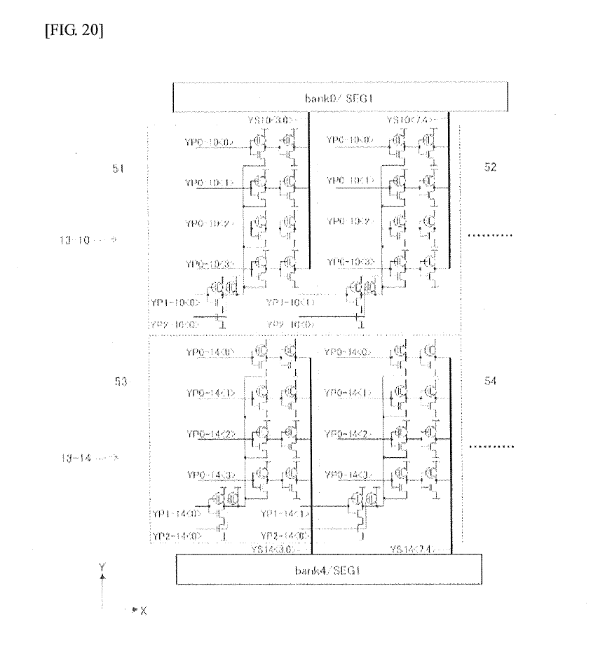

FIG. 20 is a circuit diagram of the column decoder 13.

FIG. 20 illustrates a portion of a column decoder 13-10 assigned to the segment SEG1 of the memory bank bank0, and a portion of a column decoder 13-14 assigned to the segment SEG1 of memory bank4. The column decoder 13-10 is a circuit that activates one of multiple column selection lines YS10, and FIG. 20 illustrates a driver block 51 that drives the column selection lines YS10 to YS10, and a driver block 52 that drives the column selection lines YS10 to YS10. Similarly, column decoder 13-14 is a circuit that activates one of multiple column selection lines YS14, and FIG. 20 illustrates a driver block 53 that drives the column selection lines YS14 to YS14, and a driver block 54 that drives the column selection lines YS14 to YS14.

The driver blocks 51 to 54 have the same circuit configurations as each other, and pre-decoder signals YP0 to YP2 that are different from each other are input. For example, the column selection lines YS10 to YS10 are driven based on the pre-decoder signals YP0-10 to YP0-10, under the condition that pre-decoder signals YP0-10 to YP0-10, YP1-10, and YP2-10 are input into the driver block 51 and either the pre-decoder signal YP1-10 or YP2-10 is activated at a high level.

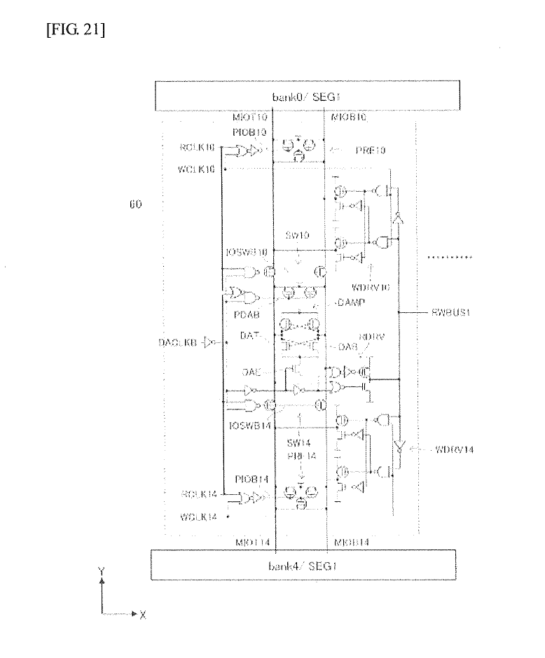

FIG. 21 is a circuit diagram of an amplifier circuit 15.

FIG. 21 illustrates an amp block 60 assigned to a read write bus RWBUS1 of the type (B) amplifier circuit 15. The amp block 60 is connected to the main I/O line pair MIOT10 and MIOB10 assigned to the segment SEG1 of the memory bank bank0 and the main I/O line pair MIOT14 and MIOB14 assigned to the segment SEG1 of the memory bank bank4, and during the read operation, the read data read through the main I/O line pair MIOT10 and MIOB10 or the main I/O line pair MIOT14 and MIOB14 is output to the read write bus RWBUS1. Furthermore, during the write operation, the write data supplied through the read write bus RWBUS1 is output to the main I/O line pair MIOT10 and MIOB10 or the main I/O line pair MIOT14 and MIOB14.

The amp block 60 includes pre-charge circuits PRE10 and PRE14, write drivers WDRV10 and WDRV14, a data amp DAMP, and a read driver RDRV.

The pre-charge circuits PRE10 and PRE14 are assigned respectively to the memory banks bank0 and bank4, and a pre-charge is performed for the main I/O line pair MIOT10 and MIOB10, and the main I/O line pair MIOT14 and MIOB14 when the pre-charge signals PIOB10 and PIOB14 are respectively activated at a low level. The pre-charge signal PIOB10 is the OR signal of the read clock signal RCLK10 and the write clock signal WCLK10, and therefore, the main I/O line pair MIOT10 and MIOB10 is pre-charged to have the same potential during the period when both the read clock signal RCLK10 and the write clock signal WCLK10 are in a state of deactivation. In the same manner, the pre-charge signal PIOB14 is the OR signal of the read clock signal RCLK14 and the write clock signal WCLK14, and therefore, the main I/O line pair MIOT14 and MIOB14 is pre-charged to have the same potential during the period when both the read clock signal RCLK14 and the write clock signal WCLK14 are in a state of deactivation.

The write drivers WDRV10 and WDRV14 are respectively assigned to the memory bank bank0 and bank4, and when each of the write clock signals WCLK10 and WCLK14 is activated at a high level, each drives the main I/O line pair MIOT10 and MIOB10 and the main I/O line pair MIOT14 and MIOB14 based on the write data supplied through the read write bus RWBUS1.

The data amp DAMP is assigned in common to the memory banks bank0 and bank4, and is activated by the enable signal DAE having an identical waveform to the data amp clock signal DACLKB. The data amp DAMP is connected to the main I/O line pair MIOT10 and MIOB10 through an I/O switch SW10, and is connected to the main I/O line pair MIOT14 and MIOB14 through an I/O switch SW14. The I/O switch SW10 is controlled by a switch signal IOSWB10, and the I/O switch SW14 is controlled by a switch signal IOSWB14. The switch signal IOSWB10 is activated when the read clock signal RCLK10 is at a high level and the data amp clock signal DACLKB is at a low level, and causes conduction of the I/O switch SW 10. In the same manner, the switch signal IOSWB14 is activated when the read clock signal RCLK14 is at a high level and the data amp clock signal DACLKB is at a low level, and causes conduction of the I/O switch SW14. Furthermore, the pre-charge signal PDAB is activated when both the read clock signals RCLK10 and RCLK14, and the data amp clock signal DACLKB are at a low level, and sense nodes DAT and DAB of the data amp DAMP are pre-charged to have the same potential.

The read driver RDRV is connected to the sense nodes DAT and DAB of the data amp DAMP, and outputs the read data amplified by the data amp DAMP to the read write bus RWBUS1 in response to the high level activation of the data amp clock signal DACLKB.

In this manner, with the present embodiment, the data amp DAMP and the read driver RDRV of the circuit that configures the amp block 60 are shared in the segment SEG1 of a different memory bank. Here, the operation does not interfere even if the data amp DAMP and the read driver RDRV are shared between memory banks because the segments SEG1 of different memory banks are not selected at the same time.

Furthermore, even for the type (A) amplifier circuit 15 assigned to the segments SEG0 and SEG2 of the same memory bank, the same circuit as the circuit illustrated in FIG. 21 can be used, in addition to using a control signal that corresponds to each. Therefore, the data amp DAMP and the read driver RDRV are shared in different segments SEG0 and SEG2 of the same memory bank. Here, the operation does not interfere even if the data amp DAMP and the read driver RDRV are shared between segments because the segment SEG0 and the segment SEG2 of the same memory bank are not selected at the same time.

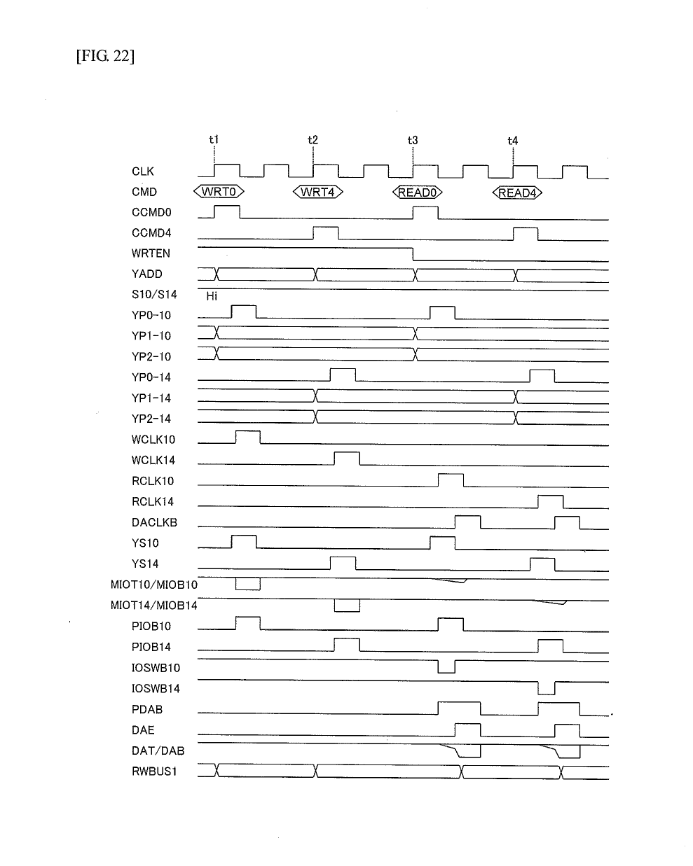

FIG. 22 is a timing diagram for describing the circuit operation illustrated in FIG. 20 and FIG. 21, and illustrates the operation at the same timing as FIG. 19. Note that in FIG. 22, a portion of the waveform illustrated in FIG. 19 is duplicated and illustrated. A portion of the description regarding the duplicated waveform is omitted.

First, one of the column selection lines YS10 is activated based on the pre-decoder signals YP0-10, YP1-10, and YP2-10 when the write command WRT0 is issued at the time t1. Through this, the main I/O line pair MIOT10 and MIOB10 is connected to the corresponding sense amp SA because one of the column switches included in segment SEG1 of memory bank bank0 is in a conducting state. Furthermore, the main I/O line pair MIOT10 and MIOB10 is driven based on the write data on the read write bus RWBUS1 through the activation of the write clock signal WCLK10. Through this, the write data is written to the segment SEG1 of the memory bank bank0.

Next, one of the column selection lines YS14 is activated based on the pre-decoder signals YP0-14, YP1-14, and YP2-14 when the write command WRT4 is issued at the time t2. Through this, the main I/O line pair MIOT14 and MIOB14 is connected to the corresponding sense amp SA because one of the column switches included in segment SEG1 of the memory bank bank4 is in a conducting state. Furthermore, the main I/O line pair MIOT104 and MIOB14 is driven based on the write data on the read write bus RWBUS1 through the activation of the write clock signal WCLK14. Through this, the write data is written to the segment SEG1 of the memory bank bank4.

Additionally, one of the column selection lines YS10 is activated based on the pre-decoder signals YP0-10, YP1-10, and YP2-10 when the read command READ0 is issued at the time t3. Through this, the main I/O line pair MIOT10 and MIOB10 is connected to the corresponding sense amp SA because one of the column switches included in segment SEG1 of memory bank bank0 is in a conducting state. As a result, the electrical potential for the main I/O line pair MIOT10 and MIOB10 is changed based on the read data read through the sense amp SA. Furthermore, the electrical potential for the main I/O line pair MIOT10 and MIOB10 is supplied to the sense nodes DAT and DAB of the data amp DAMP because the I/O switch SW10 is conducted by the activation of the read clock signal RCLK10. Moreover, amplification operations through the data amp DAMP and driving of the read write bus RWBUS1 due to the read driver RDRV are initiated when the data amp clock signal DACLKB is activated. Through this, the read data read from the segment SEG1 of the memory bank bank0 is output to the read write bus RWBUS1.

Furthermore, one of the column selection lines YS14 is activated based on the pre-decoder signals YP0-14, YP1-14, and YP2-14 when the read command READ4 is issued at the time t4. Through this, the main I/O line pair MIOT14 and MIOB14 is connected to the corresponding sense amp SA because one of the column switches included in segment SEG1 of the memory bank bank4 is in a conducting state. As a result, the electrical potential for the main I/O line pair MIOT14 and MIOB14 is changed based on the read data read through the sense amp SA. Furthermore, the electrical potential for the main I/O line pair MIOT14 and MIOB14 is supplied to the sense nodes DAT and DAB of the data amp DAMP because the I/O switch SW14 is conducted by the activation of the read clock signal RCLK14. Moreover, amplification operations through the data amp DAMP and driving of the read write bus RWBUS1 due to the read driver RDRV are initiated when the data amp clock signal DACLKB is activated. Through this, the read data read from the segment SEG1 of the memory bank bank4 is output to the read write bus RWBUS1.

In this manner, with the present embodiment, the amplifier circuit 15 is shared in a different memory bank for a portion of segment SEG1 because each memory bank is divided into three segments SEG0 to SEG2 (6 memory blocks MB0 to MB5). However, non-exclusive access between memory banks can be guaranteed without generating competition in the read data or write data, as noted above.

Furthermore, for the present embodiment, a rectangular chip shape that is close to a square can be obtained with the layout illustrated in FIG. 12. For this reason, as described using FIG. 2, good characteristics can be obtained when two semiconductor devices 10A and 10B are stacked.

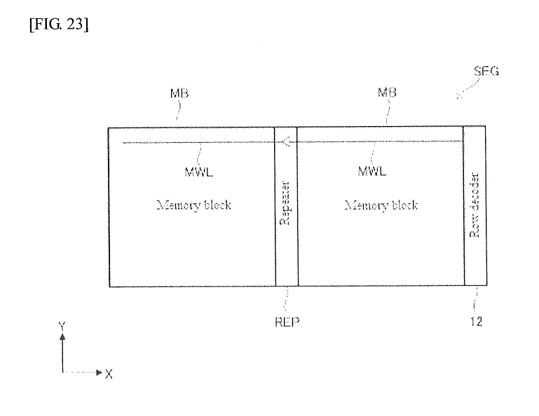

Note that in the present invention, one segment SEG is configured from two memory blocks MB, and disposing the row decoder 12 between these memory blocks MB is not required. For example, as illustrated in FIG. 23, a configuration where the row decoder 12 is disposed at the end of the segment SEG in the X direction, and a repeater REP that relays the main word line MWL is disposed between the memory blocks, may be adopted.

Other embodiments of the present invention are described below.

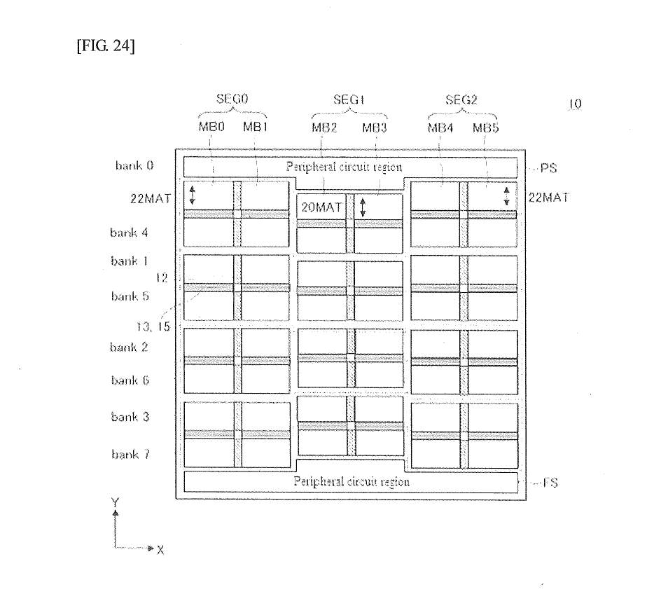

FIG. 24 is a schematic plan view illustrating the layout in a fourth example for when the semiconductor device 10 is an eight gigabit DRAM having an eight bank configuration, and corresponds to the second embodiment of the present invention.

Also in the second embodiment, one memory bank is divided into six memory blocks MB, but these six memory blocks MB are arranged in one row in the X direction. With such a layout, all the amplifier circuits 15 are shared between different memory banks. Even with this type of configuration, the same results as the first embodiment can be obtained.

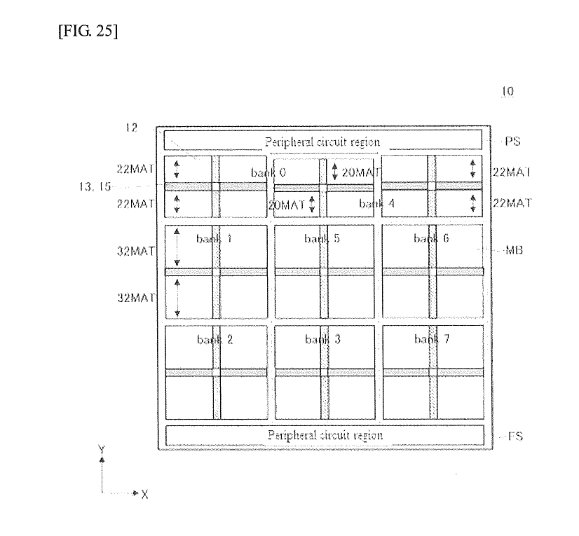

FIG. 25 is a schematic plan view illustrating the layout in a fifth example for when the semiconductor device 10 is an eight gigabit DRAM having an eight bank configuration, and corresponds to the third embodiment of the present invention.

With the third embodiment, the memory banks bank0 and bank4 are configured from six memory blocks MB, and the other memory banks are configured from four memory blocks MB. The memory banks configured from four memory blocks MB are the same as the configuration illustrated in FIG. 10 and FIG. 11, and one memory bank is configured by laying out the memory blocks MB in a matrix shape of two rows by two columns. According to such a configuration, the peripheral circuit regions PS and FS can have a more regular shape compared to the first and second embodiments.

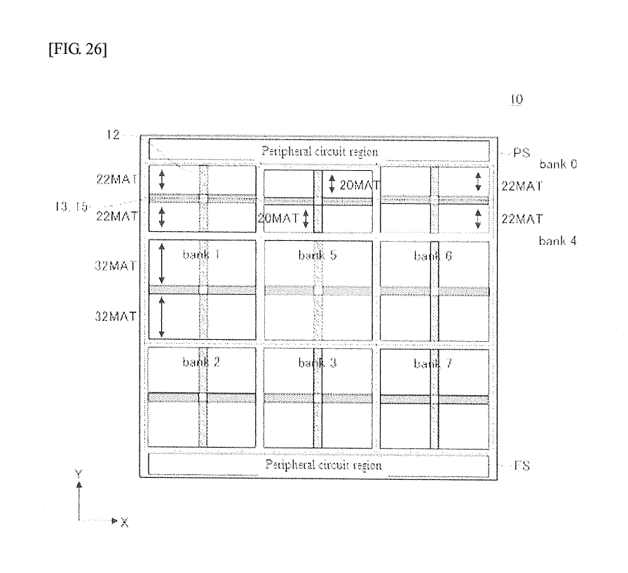

FIG. 26 is a schematic plan view illustrating the layout in a sixth example for when the semiconductor device 10 is an eight gigabit DRAM having an eight bank configuration, and corresponds to the fourth embodiment of the present invention.

With the fourth embodiment, the feature of the memory banks bank0 and bank4 being configured from six memory blocks MB, and the other memory banks being configured from four memory blocks MB is the same as the third embodiment, but the feature of the six memory blocks MB configuring memory banks bank0 and bank4 being arranged in one row in the X direction is different. Even with this type of configuration, the same results as the third embodiment can be obtained.

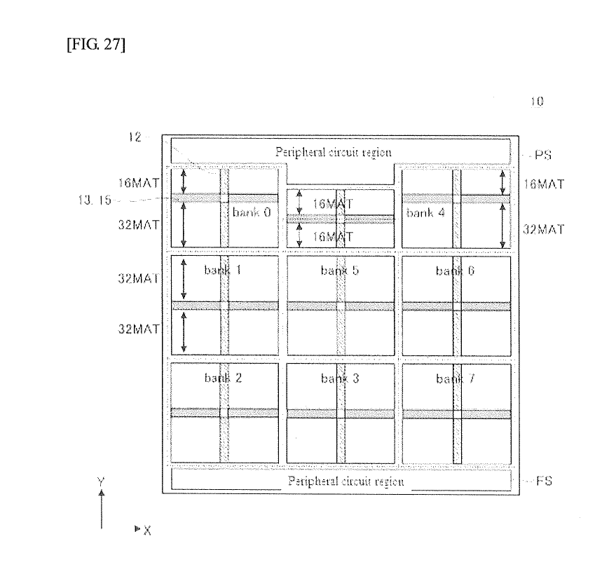

FIG. 27 is a schematic plan view illustrating the layout in a seventh example for when the semiconductor device 10 is an eight gigabit DRAM having an eight bank configuration, and corresponds to the fifth embodiment of the present invention.

With the fifth embodiment as well, the feature of the memory banks bank0 and bank4 being configured from six memory blocks MB, and the other memory banks being configured from four memory blocks MB is the same as the third embodiment, but the feature of the memory blocks MB that configure segments SEG0 and SEG1 of memory banks bank0 and bank4 each having 16 memory mats MAT in the Y direction, and the memory blocks MB that configure segment SEG2 each having 32 memory mats MAT in the Y direction, is different. According to such a configuration, for the memory banks bank0 and bank4, decoding of the address signal ADD is easier because the number of memory blocks included in each memory block MB is a power of two (the two memory mats MAT on the ends combine to be counted as one memory mat MAT).

Further, preferred embodiments of the present invention have been described, but the present invention is not limited to the above-mentioned embodiments, and can have various modifications without departing from the scope of the essence of the present invention; and it is obvious that these are included within the scope of the invention.

### REFERENCE NUMERALS

10, 10A, 10B: semiconductor device
10a to 10d: edge
11: memory cell array
12: row decoder
13: column decoder
14: sense circuit
15: amplifier circuit
20: access control circuit
21: command address tem-Anal
22: command address input circuit
23: address latch circuit
24: command decoder circuit
25: column address control circuit
26: timing signal generator circuit
30: data input-output circuit
31: data terminal
4: power circuit
41, 42: power terminal
51 to 54: driver block
60: amp block
ARY: memory cell array region
BL: bit line
BW: bonding wire
DAMP: data amp
DAT, DAB: sense node
FS, PS: peripheral circuit region
MAT: memory mat
MB: memory block
MC: memory cell
MIOT, MIOB: main I/O line pair
MWL: main word line
P: pad electrode
PRE10, PRE14: pre-charge circuit
RDRV: read driver
REP: repeater
RWBUS1: read write bus
SA: sense amp
SEG: segment
SW10, SW14: switch
SWD: sub-word driver
SWL: sub-word line
WDRV10, WDRV14: write driver
WL: word line
YS: column selection line
Z: empty space
bank: memory bank

What is claimed is:

1. A semiconductor device comprising a plurality of memory banks including a first memory bank that can be non-exclusively accessed;
the plurality of memory banks including a row decoder that selects one of a plurality of main word lines based on a row address, a column decoder that selects one of a plurality of column selection lines based on a column address, and a memory cell array made up of a plurality of memory cells selected by the plurality of main word lines and the plurality of column selection lines; and
the memory cell array included in the first memory bank being divided into a plurality of memory blocks that differ by a power of two and that are defined by the extending range of one of the plurality of main word lines and one of the plurality of column selection lines that intersect each other.

2. The semiconductor device according to claim 1, wherein the plurality of memory blocks comprises first through third memory blocks,
the first through third memory blocks include a plurality of memory mats each selected by the plurality of main word lines,
and the number of the plurality of memory mats included in the first memory block is different than the number of the plurality of memory mats included in the second memory block.

3. The semiconductor device according to claim 2, wherein the number of the plurality of memory mats included in the first memory block is equal to the number of the plurality of memory mats included in the third memory block.

4. The semiconductor device according to claim 2, wherein the number of the plurality of memory mats included in the first through third memory blocks is a number that differs by a power of two.

5. The semiconductor device according to claim 2, wherein the number of the plurality of memory mats included in the first through third memory blocks is a power of two for each case.

6. The semiconductor device according to claim 1, wherein the plurality of memory banks includes a second memory bank,
the memory cell array included in the second memory bank is divided into a plurality of memory blocks which differs by a power of two,
the plurality of memory blocks included in the second memory bank includes fourth through sixth memory blocks,
the first memory block and one of either the third or fourth memory blocks are disposed so as to be adjacent in a first direction,
the second memory block and the fifth memory are disposed so as to be adjacent in the first direction,
and the other of the third and fourth memory blocks and the sixth memory block are disposed so as to be adjacent in the first direction.

7. The semiconductor device according to claim 6, further provided with a data amplifier disposed between the second memory block and the fifth memory block and assigned in common to the second memory block and the fifth memory block.

8. The semiconductor device according to claim 1, wherein the plurality of memory banks includes a third memory bank, and the memory cell array included in the third memory bank is divided into memory blocks to the power of two.

9. A semiconductor device comprising a plurality of memory banks including a first memory bank that can be non-exclusively accessed, the plurality of memory banks each including a row decoder that selects one of a plurality of main word lines based on a row address, a column decoder that selects one of a plurality of column selection lines based on a column address, and a memory cell array made up of a plurality of memory cells selected by the plurality of main word lines and the plurality of column selection lines;
the memory cell array included in the first memory bank being divided into a plurality of memory blocks that include at least a first and a second memory block and that are defined by the extending range of one of the plurality of main word lines and one of the plurality of column selection lines that intersect each other;
the plurality of memory blocks including a plurality of memory mats each selected by the plurality of main word lines; and
the number of the plurality of memory mats included in the first memory block being different than the number of the plurality of memory mats included in the second memory block.

10. The semiconductor device according to claim 9, wherein the plurality of memory banks further includes a third memory block,
and the number of the plurality of memory mats included in the first memory block is equal to the number of the plurality of memory mats included in the third memory block.

11. The semiconductor device according to claim 10, wherein the number of the plurality of memory mats included in the first through third memory blocks is a number that differs by a power of two for each case.

12. The semiconductor device according to claim 9, wherein the plurality of memory banks includes a second memory bank,
the memory cell array included in the second memory bank is divided into a plurality of memory blocks including at least a fourth and a fifth memory block,
the number of the plurality of memory mats included in the first memory block is different than the number of the plurality of memory mats included in one of the fourth or the fifth memory blocks, and
the number of the plurality of memory mats included in the second memory block is different than the number of the plurality of memory mats included in one of either the fourth or the fifth memory blocks.

13. The semiconductor device according to claim 12, wherein the number of the plurality of memory mats included in the fourth memory block is equal to the number of the plurality of memory mats included in the fifth memory block.

14. The semiconductor device according to claim 13, wherein the number of the plurality of memory mats included in the fourth and the fifth memory blocks is a power of two for both cases.

15. A semiconductor device comprising: a first memory bank including first through third memory blocks,
a second memory bank including fourth through sixth memory blocks,
a first lead amplifier assigned in common to the first memory block and the third memory block,
a second lead amplifier assigned in common to the second memory block and the fifth memory block, and
a third lead amplifier assigned in common to the fourth memory block and the sixth memory block.

16. The semiconductor device according to claim 15 wherein, the plurality of memory blocks each includes a plurality of memory mats,
the number of the plurality of memory mats included in the second memory block is different than the number of the plurality of memory mats included in at least one of the first or third memory blocks, and
the number of the plurality of memory mats included in the fifth memory block is different than the number of the plurality of memory mats included in at least one of the fourth or sixth memory blocks.

17. The semiconductor device according to claim 16, wherein the number of the plurality of memory mats included in the first through sixth memory blocks is a number that differs by a power of 2 for each case.

18. The semiconductor device according to claim 17, further comprising a third memory bank including seventh and eighth memory blocks,
wherein the number of the plurality of memory mats included in the seventh memory block is equal to the number of the plurality of the memory mats included in the eighth memory block, and is different than the number of the plurality of memory mats included in one of the first through sixth memory blocks.

19. The semiconductor device according to claim 18, wherein the number of the memory blocks included in the first memory bank is different than the number of memory blocks included in the third memory bank.

20. The semiconductor device according to claim 16, wherein the number of the plurality of memory mats included in the first memory block is two times the number of the plurality of memory mats included in the second memory block, and
the number of the plurality of memory mats included in the fourth memory block is two times the number of the plurality of memory mats included in the fifth memory block.
